(19) United States
(12) Patent Application Publication
(10) Pub. No.: US 2018/0237562 A1
(43) Pub. Date: Aug. 23, 2018

(54) PHOTOSENSITIVE COMPOSITION, IMPRINT METHOD, AND INTERLAYER LAYER

(71) Applicant: TOSHIBA MEMORY CORPORATION, Tokyo (JP)

(72) Inventors: Hiroshi TOKUE, Yokohama (JP); Seiji MORITA, Tokyo (JP); Kei KOBAYASHI, Yokohama (JP)

(73) Assignee: TOSHIBA MEMORY CORPORATION, Tokyo (JP)

(21) Appl. No.: 15/950,536

(22) Filed: Apr. 11, 2018

Related U.S. Application Data
(62) Division of application No. 14/641,740, filed on Mar. 9, 2015.

(30) Foreign Application Priority Data
Sep. 11, 2014 (JP) 2014-185725

(51) Int. Cl. C08F 22/10; G03F 7/027; G03F 7/00; C09D 4/00; C08F 222/06; C08F 220/18; C08F 220/24

(52) U.S. Cl. CPC C08F 22/10; G03F 7/027; G03F 7/0002; C09D 4/00; C08F 220/24; C08F 222/06; C08F 220/18

(57) ABSTRACT

According to an embodiment, a photosensitive composition is provided. The photosensitive composition contains a photosensitive material. The photosensitive composition, when a whole amount of the composition is 100 pts. mass, a sum total of values each obtained by multiplying a SP value, which is a solubility parameter, by a mass percentage of a photopolymerizable monomer contained in the composition is any value within a range of 17 to 20 [(J/cm³)^{1/2}].

### CROSS-REFERENCE TO RELATED APPLICATIONS

This application is based upon and claims the benefit of priority from Japanese Patent Application No. 2014-185725, filed on Sep. 11, 2014; the entire contents of which are incorporated herein by reference.

### FIELD

An embodiment of the present invention relates to a photosensitive composition, an imprint method, and an interlayer layer.

### BACKGROUND

In recent years, an imprint method is attracting attention as one of processes used for forming a semiconductor device. In the imprint method, a template, or an original plate mold, is used. On the template, a template pattern to be transferred to a substrate such as a wafer is formed. Then, during imprint processing, a photocurable organic material (resist) is made into a droplet and is dropped on the substrate by an inkjet. Then, the template is brought into contact with the droplet of the resist, whereby the resist is pushed and enlarged.

Moreover, in a state where the template is in contact with the resist, the resist is irradiated with light. Accordingly, the resist is hardened, and the template is released from the hardened resist, whereby a resist pattern is formed on the substrate.

### BRIEF DESCRIPTION OF THE DRAWINGS

FIG. 1 is a view illustrating a configuration of as imprint device according to an embodiment;

FIGS. 2A to 2D are views illustrating a processing procedure of an imprint process according to the embodiment;

FIG. 3 is a table illustrating a SP value of molecular contaminants;

FIGS. 4A and 4B are views each illustrating a configuration of a main component of a resist;

FIGS. 5A and 5B are views each illustrating structure of an acryloyl group or a methacryloyl group;

FIGS. 6A to 6E are tables each illustrating a composition example of the resist;

FIG. 7 is a table illustrating a SP value of monomers; and

FIGS. 8A to 8D are views illustrating an imprint process in which a resist that does not dissolve the molecular contaminant is used.

### DETAILED DESCRIPTION

According to an embodiment, a photosensitive composition is provided. The photosensitive composition contains a photosensitive material. In the photosensitive composition, when a whole amount of the composition is 100pts. mass, a sum total of values each obtained by multiplying a SP value, which is a solubility parameter, by a mass percentage of a photopolymerizable monomer contained in the composition is any value within a range of 17 to 20[(J/cm³)^{1/2}].

Hereinafter, a photosensitive composition, an imprint method, and an interlayer layer according to an embodiment are described in detail with reference to the attached drawings. Note that the present invention is not to be limited by the embodiment.

### Embodiment

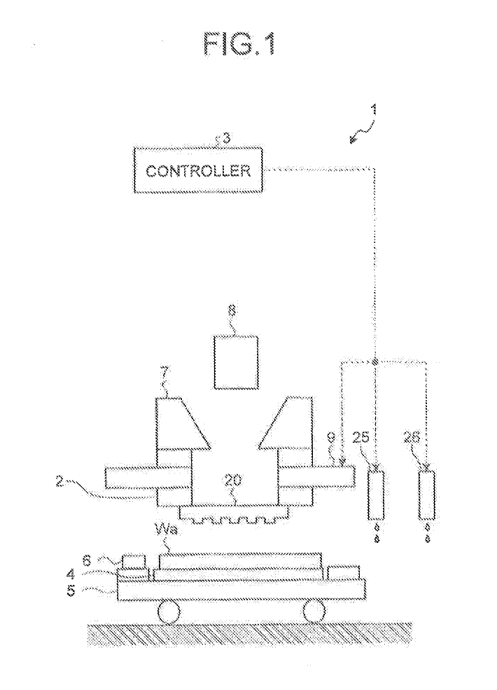

FIG. 1 is a view illustrating a configuration of an imprint device according to the embodiment. An imprint device 1 is a device that transfers a template pattern of a template 20, which is a mold substrate, to a substrate to be transferred such as a wafer Wa. The imprint device 1 forms a pattern on the wafer Wa using an imprint method such as an optical nanoimprint lithography method. The template 20 is an original plate mold, and the template pattern is a circuit pattern and the like transferred to the wafer Wa.

The imprint device 1 of the embodiment executes imprint processing using a resist (for example, a photosensitive composition such as a photocurable organic material; containing, as a main component, a material capable of dissolving a molecular contaminant. The imprint device 1 also forms an adhesion layer containing, as a main component, a material capable of dissolving the molecular contaminant in a lower layer of the resist.

The imprint device 1 is provided with an original plate stage 2, a controller 3, a substrate chuck 4, a sample stage 5, a reference mark 6, an alignment sensor 7, an UV light source 9, a stage base 9, a liquid dropping device 25, and a coating device 26.

The wafer Wa is placed on the sample stage 5, and the sample stage 5 moves within a place surface (horizontal surface) parallel to the wafer Wa placed thereon. The sample stage 5, when an adherence agent is applied to the wafer Wa, moves the wafer Wa underneath the coating device 26. The sample stage 5, when the resist is dropped as a transfer material on the wafer Wa, moves the wafer Wa underneath the liquid dropping device 25. The sample stage 5, when impression processing is performed on the wafer Wa, moves the wafer Wa underneath the template 20.

On the sample stage 5, there is provided the substrate chuck 4. The substrate chuck 4 fixes the wafer Wa at a predetermined position on the sample stage 5. On the sample stage 5, there is also provided the reference mark 6. The reference mark 6 is a mark for detecting a position of the sample stage 5, and it is used for alignment when the wafer Wa is loaded on the sample stage 5.

The original plate stage 2 is provided on a side of the wafer Wa, or a bottom face side of the stage base 9. The original plate stage 2 fixes the template 20 to a predetermined position from a back surface side (a side of a surface on which the template pattern is not formed) of the template 20 by vacuum suction or the like.

The stage base 9 supports the template 20 by the original plate stage 2 as well as presses the template pattern of the template 20 against the resist on the wafer Wa. The stage base 9 performs pressing of the template 20 against the resist and releasing of the template 20 from the resist by moving is a vertical direction. The alignment sensor 7 is provided on the stage base 9. The alignment sensor 7 is a sensor that performs position detection of the wafer Wa and position detection of the template 20.

The liquid dropping device 25 is a device that crops the resist on the wafer Wa by an inkjet method. The liquid dropping device 25 is provided with an inkjet head (not illustrated) having a plurality of micropores that jets a droplet of the resist.

The coating device 26 is a device that applies the adherence agent to the wafer Wa by a method such as a spin coat method. By applying the adherence agent to the wafer Wa, an interlayer layer such as an adhesion layer 11 described below is formed on the wafer Wa. The adhesion layer 11, which is a layer between the resist and the wafer Wa, allows the resist to adhere to the wafer Wa. In other words, the adhesion layer 11 is a layer that enhances adhesion Between the resist and the wafer Wa. Both of the adhesion layer 11 and the resist are imprint materials.

The coating device 26 applies the adherence agent to the wafer Wa before the resist is dropped on the wafer Wa. Accordingly, the coating device 26 forms, for example, the adhesion layer 11 having thickness of 5 nm on the wafer Wa.

The UV light source 8 is a light source that is provided above the stage base 9 and radiates UV light. In a state where the template 20 is pressed against the resist, the UV light source 6 radiates the UV light from above the template 20. Note that the light (visible light or invisible light) radiated on the template 20 is not limited to the UV light and may be light of any wavelength.

The controller 3 is connected to each of constituent elements of the imprint device 1 and controls each of the constituent elements. FIG. 1 is a view illustrating the controller 3 being connected to the liquid dropping device 25, the coating device 26, and the stage base 9; however, connection with another constituent element is not illustrated.

When imprinting is performed on the wafer Wa, the wafer Wa placed on the sample stage 5 is moved directly underneath the coating device 26. Then, the adherence agent is applied to the wafer Wa. Subsequently, the wafer Wa placed on the sample stage 5 is moved directly underneath the liquid dropping device 25. Then, the resist is dropped at a predetermined shot position on the adhesion layer 11 of the wafer Wa.

The resist to be dropped on the wafer Wa contains, as a main component, a material capable of dissolving the molecular contaminant. For example, as the main component of the resist, a material is used with which a difference between a solubility parameter (SP) value of the main component of the resist and a SP value of the molecular contaminant to be dissolved is within a first predetermined range (for example, 1.67 to 2.21).

Similarly, the adhesion layer 11 (adherence agent) contains, as a main component, a material capable of dissolving the molecular contaminant. For example, as the main component of the adhesion layer 11, a material is used with which a difference bet ween a SP value of the main component of the adhesion layer 11 and the SP value of the molecular contaminant to be dissolved is within a second predetermined range (for example, 1.67 to 2.21) is used.

The SP value is a parameter indicating solubility. For example, solubility of a first material in a second material is determined by a difference between a SP value of the first material and a SP value of the second material. Therefore, in the embodiment, the resist composed of a main component having a SP value corresponding to that of the molecular contaminant is used. Also, the adhesion layer 11 composed of a main component having a SP value.

In the resist of the embodiment, when a whole amount of a composition is 100 pts. mass, a sum total of values each obtained by multiplying a SP value by a mass percentage of a photopolymerizable monomer contained in the composition is any value within a range of 17 to 20 [(J/cm³)^{1/2})]. For adhesion layer 11 of the embodiment, when a whole amount of a contained component is 100 pts. mass, a sum total of values each obtained by multiplying a SP value, which is a solubility parameter, by a mass percentage of each component contained in the contained component is any value within a range of 17 to 21 [(J/cm³)^{1/2})].

When the resist is dropped, in the coating device 26 in a previous process, during conveyance in a clear room, and the like, the molecular contaminant may adhere to an upper surface side of the wafer Wa. The molecular contaminant exists on the wafer Wa in a state of being sucked by energy of a weak van der Waals force. Therefore, the SP value of the main component of the resist is set. for example, based on the SP value of the molecular contaminant by the time the resist is filled in the template pattern.

The SP value of the main component of the adhesion layer 11 is set, for example, based on the SP value of the molecular contaminant existing on the upper surface side of the wafer Wa when the resist is dropped or when the adhesion layer 11 is applied. The main component of the adhesion layer 11 is the substance capable of dissolving the molecular contaminant by the time the resist is filled in the template pattern.

Note that the molecular contaminant may be dissolved in the resist or the adhesion layer 11 at any timing as long as a resist pattern does not become a pattern failure.

After the resist has been dropped on the wafer Wa, the wafer Wa on the sample stage 5 is moved directly underneath the template 20. Then, the template 20 is pressed against the resist on the wafer Wa.

After the template 20 has been brought into contact with the resist for a predetermined time, in this state, the UV light source 8 irradiates the resist and hardens it, whereby a transfer pattern corresponding to the template pattern is patterned on the resist on the wafer Wa. Subsequently, the imprint processing is performed on a next shot.

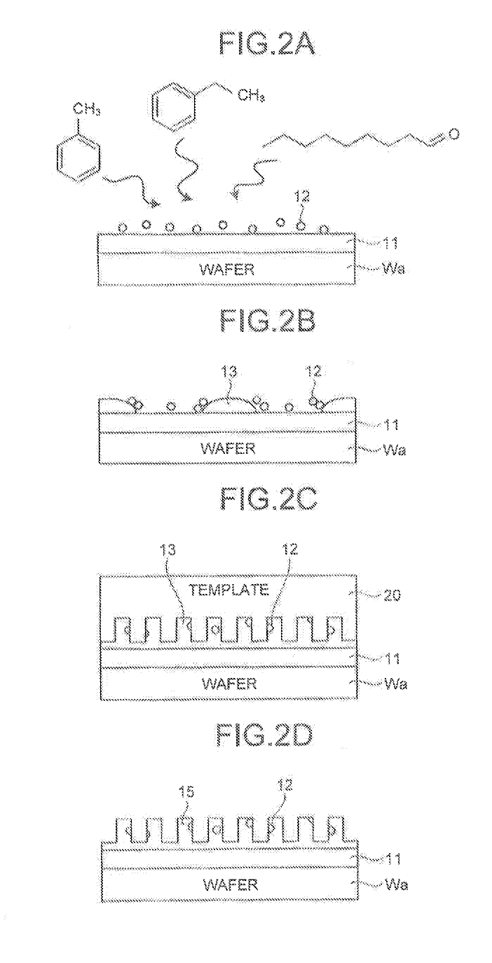

Next, processing procedure of an imprint process is described, FIGS. 2A to 2D are views illustrating the processing procedure of the imprint process according to the embodiment. FIGS. 2A to 2D are sectional views illustrating the wafer Wa, the template 20, and the like during the imprint process.

As illustrated in FIG. 2A, the adherence agent is applied to an upper surface of the wafer Wa, whereby the adhesion layer 11 is formed. In the clean room where the imprint device 1 is disposed, for example, a molecular contaminant 12 such as toluene, ethylbenzene, and cyclohexane floats.

Also in the clean room, it has been known that there exists, as the molecular contaminant 12, for example, an acid gas such as SOₓ, NOₓ, HCl, Cl₂, and HF, a basic gas such as NH₃ and amine, an organic substance such as siloxane and dioctyl phthalate (DOP), and a dopant such as boron and phosphorus used for manufacturing of a semiconductor device.

The above-described molecular contaminant 12 may adhere to the wafer Wa. In the embodiment, the adhesion layer 11 is formed on the wafer Wa by the coating device 26 by the spin cost method. Then, a difference between the SP value of the main component of the adherence agent and the SP value of the molecular contaminant 12 to be dissolved is within the second predetermined range. Therefore, the adhesion layer 11 dissolves the molecular contaminant 12 on the wafer Wa. As a result, the molecular contaminant 12 on the wafer Wa is removed.

After the adhesion layer 11 has been formed on the wafer Wa, as illustrated in FIG. 2B, a resist 13 is dropped on the upper surface of the wafer Wa. Then, as illustrate in FIG 2C, the template 20 is pressed against the resist 13.

The molecular contaminant 12 may adhere to a surface of the adhesion layer 11 and to a surface of the resist 12 between forming processing of the adhesion layer 11 and pressing processing of the template 20 against the resist 13. In the embodiment, the liquid dropping device 25 drops the resist 13 on the wafer Wa. Then, a difference between a SP value of the main component of the resist 13 and the SP value of the molecular contaminant 12 to be dissolved is within the first predetermined range. Therefore, the resist 13 dissolves the molecular contaminant 12 on the wafer Wa. As a result, the molecular contaminant 12 on the wafer Wa is removed.

When the template 20, which is formed by engraving a quartz substrate or the like, is pressed against the resist 13, the resist 13 flows into the template patterns of the template 20 by a capillary phenomenon. After the template 20 has been pressed against the resist 13, the resist 13 is filled in the template pattern for a present time.

Subsequently, the UV light is radiated from above the template 20. Accordingly, the resist 13 is hardened. Then, the template 20 is released from the hardened resist 13. Accordingly, as illustrated in FIG. 2D, a resist pattern 15, which is reversal of the template pattern, is formed on the wafer Wa.

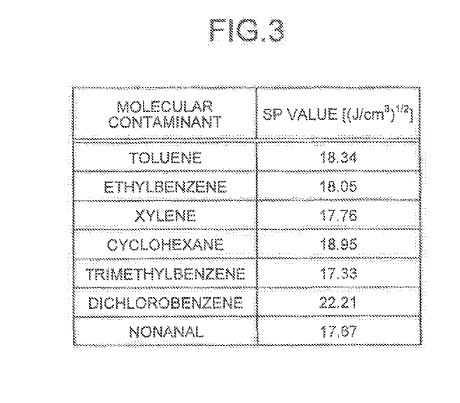

Here, the SP value of the molecular contaminant 12 is described. FIG. 3 is a table illustrating a SP value of molecular contaminants. The molecular contaminant 12 may be, for example, toluene, ethylbenzene, xylene, cyclohexane, trimethylbenzene, dichlorobenzene, and nonanal.

The SP value [(J/cm³)^{1/2}] of the toluene is 18.34, and the SP value of the ethylbenzene is 18.05 [(J/cm³)^{1/2}]. The SP value of the xylene is 17.76 [(J/cm³)^{1/2}], and the SP value of the cyclchexane is 18.95 [(J/cm³)^{1/2}]. The SP value of the trimethylbenzene is 17.33 [(J/cm³)^{1/2}], and the SP value of the dichlorobenzene is 22.21 [(J/cm³)^{1/2}]. The SP value of the nonanal is 17.67 [(J/cm³)^{1/2}].

The main component of the resist 13 may be, for example, ethylacrylate having use SP value of 18.29 [(J/cm³)^{1/2}]. Note that the SP value of the main component of the resist 13 is determined according to a type of the molecular contaminant 12 to be dissolved. For example, to dissolve the molecular contaminant 12 illustrated an FIG. 3, a material having the SP value of 17 to 21 [(J/cm³)^{1/2}] is used as the main component of the resist 13. In this way, since the material having the SP value close to that of the representative molecular contaminant 12 is used as the main component of the resist 13, the molecular contaminant 12 dissolves in the resist 13.

Similarly, the SP value of the main component of the adhesion layer 11 is determined according to the type of the molecular contaminant 12 to be dissolved. For example, to dissolve the molecular contaminant 12 illustrated in FIG. 3, a material having the SP value or 17 to 21 [(J/cm³)^{1/2}] constitutes the main component of the adhesion layer 11. In this way, since the material having the SP value close to that of the representative molecular contaminant 12 is used as the main component of the adhesion layer 11, the molecular contaminant 12 dissolves in the adhesion layer 11.

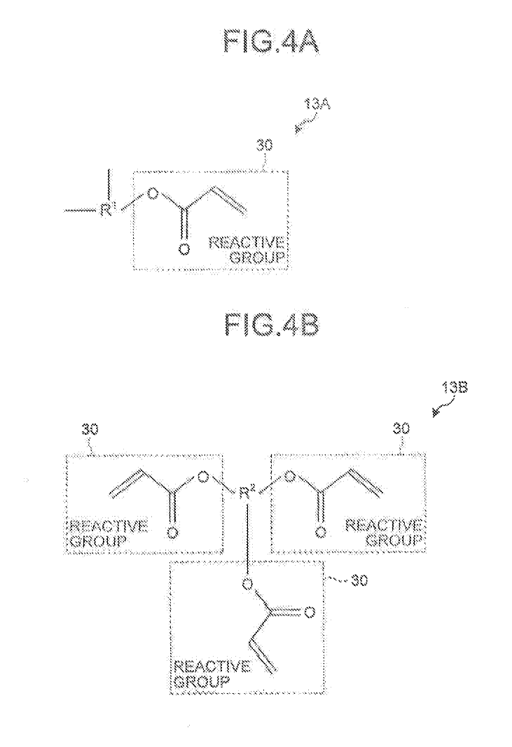

Next, a configuration of the resist 13 is described, FIGS. 4A and 4B are views each illustrating a configuration of the main component of the resist. In FIG. 4A, a resist 13A, which is a first example of the main component of the resist 13, is illustrated, and in FIG. 4B, a resist 13B, which is a second example of the main component of the resist 13, is illustrated.

In the resist 13A illustrated in FIG. 4A, one reactive group 30 is bonded to an organic group R¹. Then, the reactive group 30 bonded to R¹ is one acryloyl group. Therefore, the resist 13A is monofunctional acrylate.

In the resist 13B illustrated, in FIG. 4B, a plurality of reactive groups 30 is bonded to an organic group R². Then, each of the three reactive groups 30 bonded to R² is the acryloyl group. Therefore, the resist 13B is a polyfunctional acrylate.

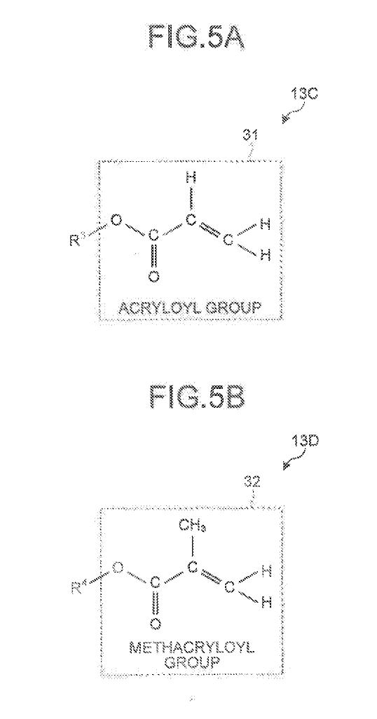

Note that the reactive group 30 bonded in the resist 13A or the resist 13B may also be a methacryloyl group. FIGS. 5A and 5B are views each illustrating structure of the acryloyl group or the methacryloyl group, In FIG. 5A, a resist 13C, which is a third example of the main component of the resist 13, is illustrated, and in FIG. 5B, a resist 13D, which is a fourth example of the main component of the resist 13, is illustrated. In the resist 13C, an acryloyl group 31 is bonded to an organic group R³. In the resist 13D, a methacryloyl group 32 is bonded to an organic group R⁴.

The acryloyl group 31 or the methacryloyl group 32 is bonded to a terminal or a side chain of a molecule of the main component contained in the resist 13. Note that the adhesion layer 11, similar to the resist 13, has at least one or more types of the reactive group 30 and an organic group and structure thereof is similar to that of the resist 13, whereby a description thereof is omitted.

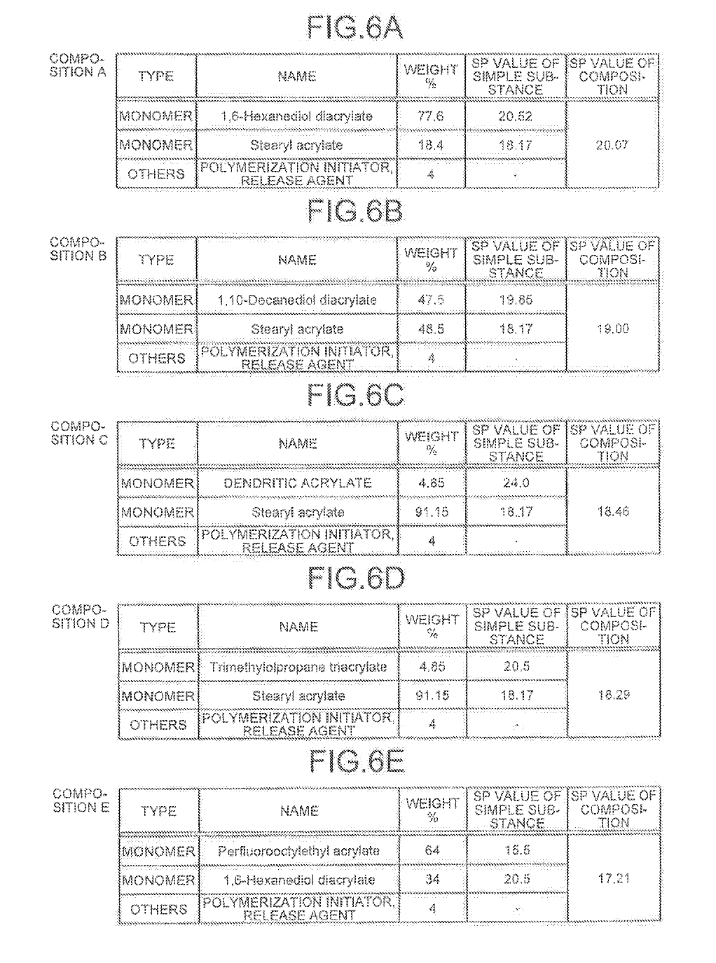

FIGS. 6A to 6E are tables each illustrating a composition example of the resist. In FIGS. 6A to 6E, the composition example of compositions A to E are illustrated. In FIGS. 6A to 6E, “type”, “name”, “weight percentage”, and “SP value of a simple substance” of a substance constituting the composition as well as “SP value of the composition” are illustrated.

Each of the compositions A to E contains a plurality of monomers and another component (polymerization initiator and release agent). For example, the composition A contains 1,6-hexanediol diacrylate and stearyl acrylate as the monomers. The 1,6-hexanediol diacrylate and the stearyl acrylate constitute 77.6 wt % and 18.4 wt %, respectively. The SP value of the 1,6-hexanediol diacrylate is 20.52 and the SP value of the stearyl acrylate is 18.17. The SP value of the composition A is 20.07.

The composition B contains 1,10-Decanediol (47.5 wt %, SP value: 19.87) and the stearyl acrylate (48.5 wt %) as the monomers. The SP value of the composition B is 19.00.

The composition C contains dendritic acrylate (4.85 wt %, SP value: 24.0) and the stearyl acrylate (91.15%) as the monomers. The SP value of the composition C is 18.46.

The composition D contains trimethylolpropane triacrylate (4.85 wt %, SP value: 20.5) and the stearyl acrylate (91.15 wt %) as the monomers. The SP value of the composition D is 18.29.

The composition E contains perfluorooctylethyl acrylate (64 wt %, SP value: 15.5) and the 1,6-hexanediol diacrylate (34 wt %) as the monomers. The SP value or the composition E is 17.21.

For example, the SP value of the composition A is calculated by using the following formula:

$$SP value of composition A = \sum ( SP value of simple substance monomer ) \times ( ratio of simple substance monomer to all monomers ) = ( SP value of 1 , 6 \text{-} hexanediol diacrylate ) \times 77.6 / ( 77.6 + 18.4 ) + ( SP value of stearyl acrylate ) \times 18.4 / ( 77.6 + 18.4 ) = 20.52 \times 77.6 / ( 77.6 + 18.4 ) + 18.17 \times 18.4 / ( 77.6 + 18.4 ) = 20.07$$

Since the compositions A to E have a property as illustrated in FIGS. 6A to 6E, for example, the resist within a range of 17 to 21[(J/cm³)^{1/2}] or the adhesion layer 11 within a range of 17 to 21 [(J/cm³)^{1/2}] are used in the embodiment. As the resist or the adhesion layer 11 of the embodiment, a monomer having the SP value within a range of 15.5 to 21 [(J/cm³)^{1/2}] is used.

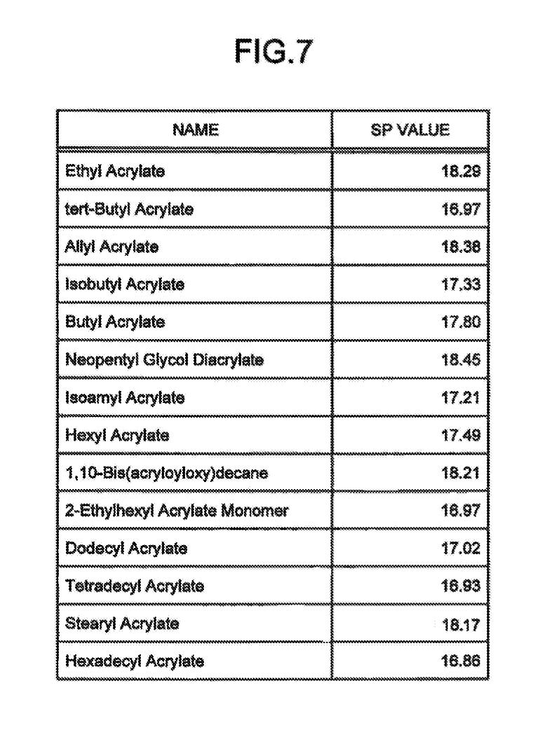

FIG. 7 is a table illustrating a SP value of monomers. As illustrated in FIG. 7, for example, the SP value of ethyl acrylate is 18.29, and the SP value of tert-Butyl acrylate is 16.97.

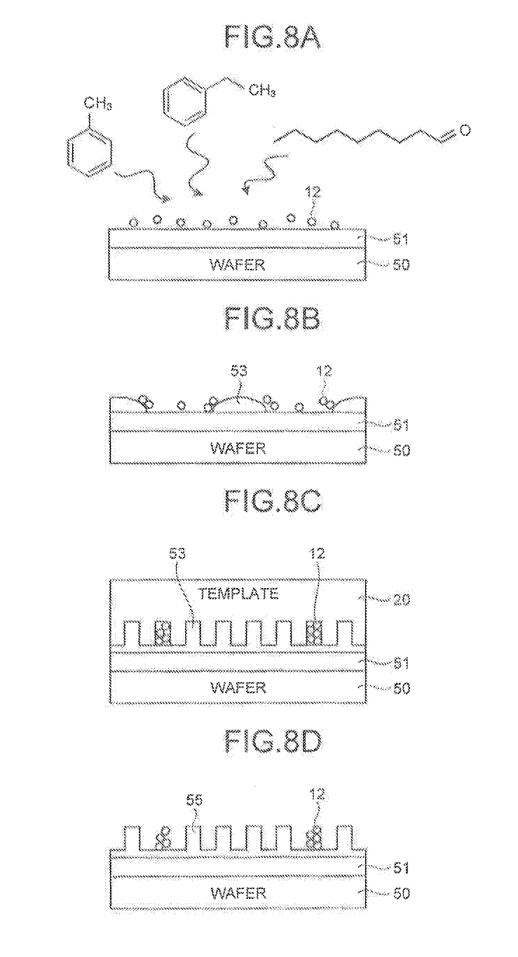

FIGS. 8A to 8D are views illustrating an imprint process in which a resist that does not dissolve the molecular contaminant is used. FIGS. 8A to 8D are sectional views illustrating a wafer 50, the template 20, and the like during the imprint process in which a resist 53 that does not dissolve the molecular contaminant 12 is used.

As illustrated in FIG. 8A, the adherence agent is applied to an upper surface of the wafer 50, whereby an adhesion layer 51 is formed. A difference between a SP value of a main component of the adhesion layer 51 and the SP value of the molecular contaminant 12 is greater than the second predetermined range. In this case, the adhesion layer 51 hardly dissolves the molecular contaminant 12 on the wafer 50 during the imprint processing.

After the adhesion layer 51 has been formed on the wafer 50, as illustrated in FIG. 8B, the resist 53 is dropped on the upper surface of the wafer 50. Here, a difference between a SP value of a main component of the resist 53 and the SP value of the molecular contaminant 12 is greater than the first predetermined range.

Subsequently, as illustrated in FIG. 8C, the template 20 is pressed against the resist 53. When the template 20 is pressed against the resist 53, the resist 53 is expanded, and the molecular contaminant 12 is condensed at a border between droplets of the resist. The resist 53 flows into the template pattern of the template 30 be the capillary phenomenon. At this time, a part where the molecular contaminant 12 has condensed becomes an empty space (void).

After the template 20 has been pressed against the resist 53, the resist 53 is filled in the template pattern for a preset time. Subsequently, the resist 53 is hardened by the UV light being radiated from above the template 20. There, the template 20 is released from the hardened resist 53.

Accordingly, as illustrated In FIG. 8D, a resist pattern 55, which is reversal of the template pattern, is formed on the wafer 50. In the resist pattern 55, at least a part of the pattern becomes the empty space (void) due to condensation and segregation of the molecular contaminant 12, whereby it becomes a pattern defect and a failure part.

On the other hand, in the embodiment, the imprint processing is executed by using the resist 13 containing, as the main component, a substance with which a difference in the SP value with the molecular contaminant 12 is smaller than before. For example, when the SP value of a major molecular contaminant is 17 to 18 [(J/cm³)^{1/2}], the SP value of the resist 53 an the like is about 22 to 25 [(J/cm³)^{1/2}]. On the other hand, the SP value of the resist 13 used in the embodiment is 17 to 18 [(J/cm³)^{1/2}], which is equivalent to the SP value of the major molecular contaminant. Therefore, it is possible to prevent occurrence 12. As a result, it is possible to suppress a decrease in a yield of the semiconductor device manufactured by using the imprint processing.

The imprint processing by the imprint device is performed, for example, for each layer in a wafer process. Then, the semiconductor device (semiconductor integrated circuit) is manufactured by the wafer process being repeated for each of the layers.

Specifically, after the template 20 has been manufactured, the imprint device 1 forms the adhesion layer 11 on the wafer Wa and subsequently drops the resist 13 on the wafer Wa. Subsequently, the imprint device 1 presses the template 20 against the resist 13 and forms the resist pattern using tire resist 13. Then, using the resist pattern as a mask, etching is performed on a lower layer side of the wafer Wa. Accordingly, an actual pattern corresponding to the resist pattern is formed on the wafer Wa. When the semiconductor device is manufactured, the imprint processing, etching processing, and the like using the above-described adhesion layer 11 and the resist 13 are repeated for each of the layers.

Note that in the embodiment, a case in which the imprint processing is executed by using the adhesion layer 11 has been described; however, the imprint processing may also be executed without using the adhesion layer 11. Also, the SP value of the adhesion layer 11 may be an arbitrary value.

The resist 13 may be applied to the wafer Wa by the spin coat method and the like. The adherence agent may be dropped on a wafer by the inkjet method.

Before the adherence agent is applied, cleaning processing of the wafer Wa may be executed. Before the adherence agent is applied or the resist 13 is dropped, cleaning processing of the imprint device 1 may also be executed.

It is also possible to set a SP value corresponding to the molecular contaminant 12 that is not removable in the cleaning processing to the adherence agent or the resist 13. In this case, for example, the molecular contaminant 12 having a first SP value is removed in the cleaning processing, and the molecular contaminant 12 having a second SP value is removed in the adhesion layer 11 or the resist 13.

Also, an interlayer layer such as the above-described adhesion layer 11 may be any member as long as it is a layer (member) disposed between the resist 13 and the wafer Wa. The interlayer layer such as the adhesion layer 11, for example, may contain propylene glycol monoethyl ether acetate (1-methoxy-2-propanol acetate) (SP value is 18.8 [(J/cm³)^{1/2}] as the main component.

In this way, in the embodiment, the SP value of the main component of the resist 13, which is the imprint material, is any value within the range of 17 to 21.Therefore, even in a case where the molecular contaminant 12 exists in a process atmosphere during the imprint processing, it is possible to dissolve the molecular contaminant 12 in the resist 13. Accordingly, it is possible to suppress the condensation and segregation or the molecular contaminant 12, whereby it is possible to decrease the pattern failure caused by the molecular contaminant 12

Since the SP value of the main component of the adhesion layer 11 is any value within the range of 17 to 21 [(J/cm³)^{1/2}], it is possible to dissolve the molecular contaminant 12 in the adhesion layer 11. Since the SP value of the main component of the resist 13 is any value within the range of 17 to 20 [(J/cm³)^{1/2}] even in a case where the resist 13 is dropped by the inkjet method, it is possible to dissolve the molecular contaminant 12 in the resist 13.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1-19. (canceled)

20. A method of imprinting, the method comprising:
forming an interlayer layer on a substrate to which a template pattern formed in a template is to be transferred; and
dropping a photosensitive composition on the interlayer layer; and
forming a resist pattern corresponding to the template pattern on the substrate by pressing the template against the photosensitive composition, wherein
the photosensitive composition contains a photosensitive material, and, when a total amount of monomers in the photosensitive composition is 100 pts. mass, a sum total of values is within a range of 17 to 20 (J/cm³)^{1/2}, each of the values being obtained by multiplying a SP value, which is a solubility parameter of each component contained in the photosensitive composition, by a mass percentage of each component contained in the photosensitive composition, and,
when a total amount of a component contained in the interlayer layer is 100 pts. mass, a sum total of values is within a range of 17 to 21 (J/cm³)^{1/2}, each of the values being obtained by multiplying a SP value, which is a solubility parameter of each component contained in the interlayer layer, by a mass percentage of each component contained in the interlayer layer.

21. The method of imprinting according to claim 20, wherein
the photosensitive composition is dropped on the substrate by an inkjet method.

22. The method of imprinting according to claim 20, wherein
the photosensitive composition is a substance capable of dissolving a molecular contaminant by the time the photosensitive composition is filled in the template pattern.

23. The method of imprinting according to claim 20, wherein
the interlayer layer is a substance capable of dissolving a molecular contaminant by the time the photosensitive composition is filled in the template pattern.

24. The method of imprinting according to claim 20, wherein
a main component of the photosensitive composition is one or more acryloyl groups, or is one or more methacryloyl groups.

25. The method of imprinting according to claim 20, wherein
a main component of the interlayer layer is one or more acryloyl groups, or is one or more methacryloyl groups.

26. The method of imprinting according to claim 20, wherein,
when a total amount of monomers in the photosensitive composition is 100 pts. mass, a sum total of values is within a range of 17 to 18 (J/cm³)^{1/2}, each of the values being obtained by multiplying a SP value, which is a solubility parameter of each component contained in the photosensitive composition, by a mass percentage of each component contained in the photosensitive composition, and,
when a total amount of a component contained in the interlayer layer is 100 pts. mass, a sum total of values is within a range of 17 to 18 (J/cm³)^{1/2}, each of the values being obtained by multiplying a SP value, which is a solubility parameter of each component contained in the interlayer layer, by a mass percentage of each component contained in the interlayer layer.

27. The method of imprinting according to claim 20, wherein
a main component of the photosensitive composition has the same composition as a main component of the interlayer layer.

28. A method of imprinting, the method comprising:
dropping a photosensitive composition on a substrate to which a template pattern formed in a template is to be transferred, a main component of the photosensitive composition being a material containing an acryloyl group or a methacryloyl group, the photosensitive composition being a composition that dissolves a molecular contaminant; and
forming a resist pattern corresponding to the template pattern on the substrate by pressing the template against the photosensitive composition.

29. The method of imprinting according to claim 28, further comprising:
forming an interlayer layer between the photosensitive composition and the substrate by forming the interlayer layer on the substrate before the photosensitive composition is dropped on the substrate, wherein
a main component of the interlayer layer being a material containing an acryloyl group or a methacryloyl group, the interlayer layer being a layer that dissolves a molecular contaminant.
